(19) United States
(12) Patent Application Publication
(10) Pub. No.: US 2010/0279031 A1
(43) Pub. Date: Nov. 4, 2010

(54) Seashell Decoration and Its Processing

(76) Inventor: TZE HANG STEPHEN LEE, Dungguan (CN)

Correspondence Address: GLOBAL IP SERVICES, 7285 W. Eagle Court, Winton, CA, 95388, US

(21) Appl. No.: 12/432,704

(22) Filed: Apr. 29, 2009

(51) Int. Cl. B44F 7/00; C23C 14/34

(52) U.S. Cl. 428/15; 204/192.1

(57) ABSTRACT

This invention discloses a seashell decoration and method for preparing a seashell decoration. This seashell decoration comprising a seashell substrate (1) and a layer of gold or ceramic film (2) on the surface of said seashell substrate (1). It is preparing by the steps of cutting, washing, coating and cooling the seashell. As the seashell substrate surface is coated with a layer of gold or ceramic film, it achieves very even metallic or ceramic color. Also, with the film tight on its surface, the film displays the texture of the shell. The materials used for the processing is metal or ceramic target without any colorant, thus not polluting the environment and remaining very environmental friendly.

### FIELD OF THE INVENTION

This invention relates to the technical field of decoration materials, specially a seashell decoration and its processing.

### BACKGROUND OF THE INVENTION

The seashell is a natural product with rich and delicate textures and colors on its surface. It can serve the decoration purposes on the clock and watch faces, jewelries, glasses, and mobile phones to make it prettier. Take for example the clock and watch industry, the seashell can be used on the clock and watch faces. The one of the processing methods of seashell raw materials can be polishing, which is to change the seashell colors by spray painting technology whose operating principle is to spray the paint on the seashell back so that the seashell front is shining and retaining its original texture. Another processing method is to dye the seashell to change its colors.

Through the above processing methods, the seashells produced do not have beautiful metal luster. Meanwhile, the seashell back is colored by polishing and its front retains the original color, while the dyeing can have great harm on the seashell itself and the varied cell density of the seashell can cause uneven dyeing.

### SUMMARY OF THE INVENTION

One of the aims of this invention is to provide seashell decorations with an even metallic or ceramic color, and the original texture to solve the problems in existing technologies

Another aim of this invention is to provide an environmental-friendly processing method for the above seashell decoration.

The following technical solution is adopted in this invention to achieve the above goals.

A seashell decoration comprising a seashell substrate and a layer of metal or ceramic film on the surface of said seashell substrate. Furthermore, the metal film can be a gold film.

A method for preparing a seashell decoration comprising following steps:

a) Cutting, cut seashell raw material into seashell substrate (1);

b) Cleaning, clean the seashell substrate (1) and then dry it;

c) Film plating, put the seashell substrate in a vacuum furnace, use metal or ceramics as a target to process vacuum sputtering for coat a film on the surface of seashell substrate.

Furthermore, a step b1) of iron cleaning is processed before the step c)

This invention is beneficial in that the seashell substrate has even metallic or ceramic color thanks to the metallic or ceramic coating on the outer surface, and that it retains the seashell texture since the film is closely attached to the outer surface. The materials adopted in the processing of this invention are metal or ceramic target without any colorant. Thus, it is environmental friendly.

### BRIEF DESCRIPTION OF THE DRAWINGS

FIG. 1 is the structure diagram of the seashell decoration.

FIG. 2 is another structure diagram of the seashell decoration

FIG. 3 is the process flow chart of making the seashell decoration.

FIG. 4 is another process flow chart of making the seashell decoration.

### DETAILED DESCRIPTION OF THE INVENTION

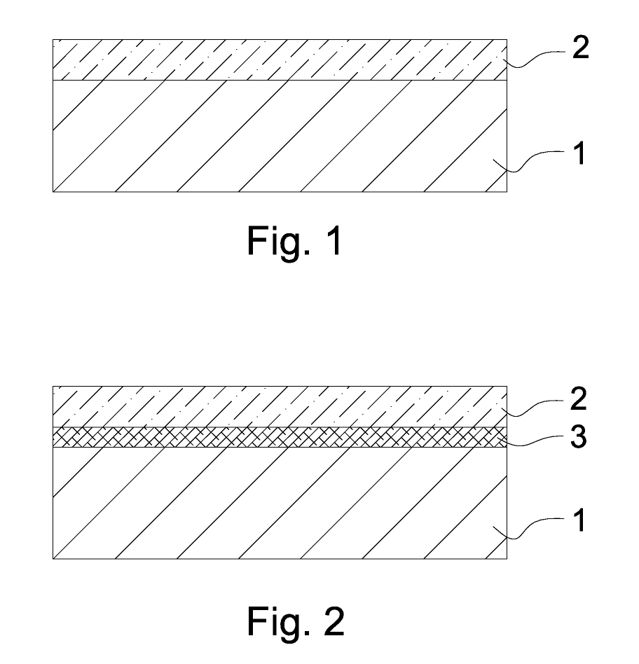

The following section illustrates this invention further with attached pictures. Please look at attached FIG. 1. A seashell decoration includes seashell substrate 1. The said substrate 1 is made of the seashell after cutting and polishing. The outer surface of substrate 1 is coated with a layer of metal or ceramic film 2, which allows the surface to have well-distributed metallic or ceramic shine. Since the film is closely attached to the outer surface of substrate 1, the seashell textures are retained.

The film 2 mentioned in this embodiment should not exceed 1 micrometer in thickness.

As shown in the FIG. 2 there is a pre-plated titanium film 3 between substrate 1 and film 2 mentioned in this embodiment.

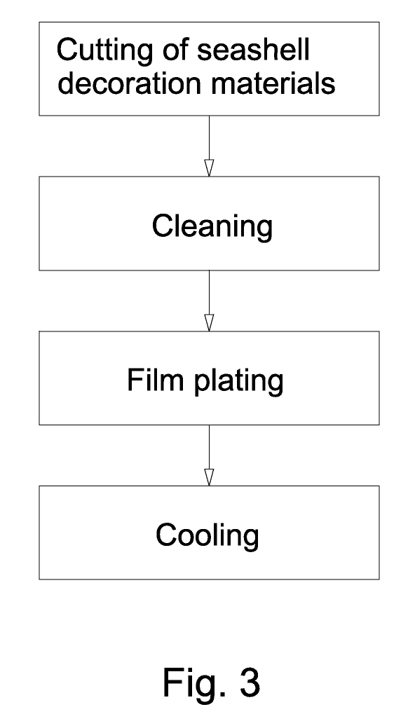

As showed in attached FIG. 3, the process of the seashell decoration is: seashell raw material cutting→cleaning→film plating→cooling. The following section gives details to each step in the process.

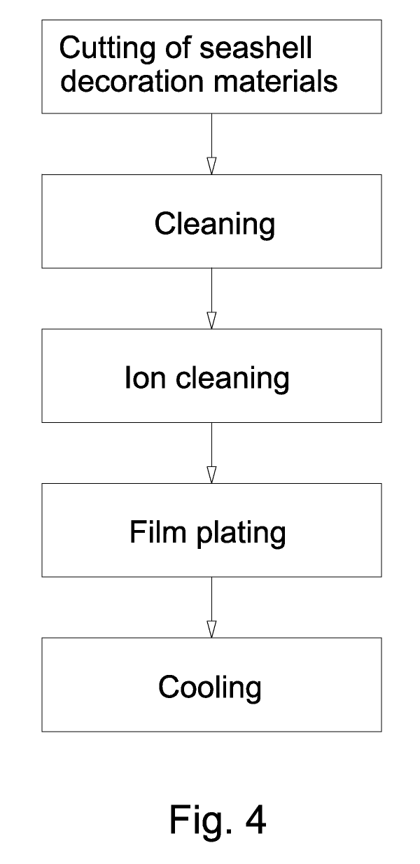

As showed in attached FIG. 4, the process of the seashell decoration is: seashell raw material cutting→cleaning→iron cleaning→film plating→cooling. The following section gives details to each step in the process.

Seashell raw material cutting: the variety of seashells can cover all kinds of seashells. From the perspective of processing, the larger the seashell, the easier the cutting, but the cost is higher. The seashell should be cut into small pieces, based on its dimension and thickness. The seashell after cutting should be between 1-2 mm in thickness and the shapes can be round, square, polygonal or others required. The dimension of seashell piece should be cut according to the requirements and the seashell variety in order to make an effective use of it or cut it as per the actual needs. The cutting can be mechanical cutting, ultrasonic cutting, laser cutting, water-jet cutting and grinding by the grinding machine.

Cleaning: clean the cut seashell substrate 1 with clean water, and dry it in low temperature, and then blow the substrate 1 surface with fire flames to dry out the moist completely, and use a piece of cotton cloth to dry it to avoid the occurrence of water streaks on the outer surface of substrate 1.

Ion cleaning: place the dried substrate 1 into the vacuum furnace and heat it up to 70° C., and then turn on the medium sputtering power supply, stimulate the titanium ions of the titanium target in the furnace which impact on the outer surface of substrate 1 to remove the remaining stains. This process of ion cleaning can not only further clean substrate 1, but also form a titanium film as thin as transparent on the outer surface of substrate 1 to vitalize substrate 1 surface and prepare it for the film plating in the next step.

Film plating: turn off the titanium target. Turn on the metal or ceramic sputtering target for the required film materials to have vacuum sputtering coating treatment. Take gold as an example. If it is needed to plate a gold film as film 2 on the surface of substrate 1, then use the medium frequency power supply to stimulate the gold target to sputter the gold ions, and lead the gold ions to the outer surface of substrate 1 and sediment to form a gold film through grid bias supply. The color and polish of film 2 plated can be determined together by the target and air that is injected into the vacuum furnace. Films 2 of different colors can be obtained by selecting different targets and the air injected. The film 2 produced by vacuum sputtering coating process should not exceed 1 micrometer in thickness. It should also has sound contact with seashell substrate 1 in a well distributed way so that the original textures and refraction of the seashell, and meanwhile displays the metallic or ceramic shine.

Cooling: since the expansion coefficient of metal is larger than that of seashell, in this embodiment, the treated seashell decoration will be cooled down in a gradient method in the vacuum furnace. It is not taken out until the furnace temperature is reduced to 60° C. to avoid the bursting caused by the inner tension inside the seashell.

What is claimed is:

1. A seashell decoration comprising a seashell substrate (1) and a layer of metal or ceramic film (2) on the surface of said seashell substrate (1).

2. The seashell decoration of claim 1, wherein said metal or ceramic film (2) does not exceed 1 micrometer in thickness.

3. The seashell decoration of claim 1, wherein there is a layer of pre-plated titanium film (3) between the seashell substrate and layer of gold or ceramic film.

4. The seashell decoration of claim 2, wherein there is a layer of pre-plated titanium film (3) between the seashell substrate and layer of gold or ceramic film.

5. The seashell decoration of claim 1, wherein the metal film (2) is a gold film.

6. A method for preparing a seashell decoration comprising following steps:
a) cutting, cut seashell raw material into seashell substrate (1);
b) cleaning, clean the seashell substrate (1) and then dry it;
c) film plating, put the seashell substrate in a vacuum furnace, use metal or ceramics as a target to process vacuum sputtering for coat a film on the surface of seashell substrate(1).

7. The method of claim 6, wherein a step b1) of iron cleaning is processed before the step c), the step b1) includes the following steps: placing the dried substrate(1) into the vacuum furnace, using titanium as the target to apply vacuum sputter, thereby further cleaning and coating the substrate(1) surface with a layer of titanium film(3).

8. The method of claim 7, wherein a temperature inside the vacuum furnace is 70° C. during step b1).

9. The method of claim 6, wherein there is a step d) after Step c): d) cooling, the seashell decoration undergoes a gradient cooling in the vacuum furnace after plating with film(2) and then take out the seashell with film after the temperature is reduced to 60° C. to get seashell decoration.

10. The method of claim 7, wherein there is a step d) after Step c: d) cooling, the seashell decoration undergoes a gradient cooling in the vacuum furnace after plating with film(2) and then take out the seashell with film after the temperature is reduced to 60° C. to get seashell decoration.

11. The method of claim 6, wherein a kind of power adopted for the vacuum sputtering coating is medium frequency power.

12. The method of claim 7, wherein a kind of power adopted for the vacuum sputtering coating is medium frequency power.

13. The method of claim 6, wherein the Step b including: wash the seashell substrate (1) in water, dry it in low temperature, then blow the outer surface of the seashell substrate (1) with flames, and finally use piece of cotton cloth to wipe up the seashell substrate (1).
